(19) United States
(12) Patent Application Publication
(10) Pub. No.: US 2019/0347979 A1
(43) Pub. Date: Nov. 14, 2019

(54) MICRO LIGHT-EMITTING DIODE DISPLAYS AND PIXEL STRUCTURES

(71) Applicant: Intel Corporation, Santa Clara, CA (US)

(72) Inventor: Khaled AHMED, Anaheim, CA (US)

(21) Appl. No.: 15/974,551

(22) Filed: May 8, 2018

(51) Int. Cl. G09G 3/32; G02B 27/09; H01L 51/52; H01L 27/32

(52) U.S. Cl. CPC G09G 3/32; G02B 27/0961; G09G 2310/0264; H01L 27/3211; G09G 2300/0439; H01L 51/5237

(57) ABSTRACT

Micro light-emitting diode displays and pixel structures are described. In an example, a micro light emitting diode pixel structure includes a plurality of micro light emitting diode devices in a dielectric layer. A transparent conducting oxide layer is disposed above the dielectric layer. A passivation layer is above the transparent conducting oxide layer, the passivation layer having an outer surface including sub-wavelength features.

### TECHNICAL FIELD

Embodiments of the disclosure are in the field of micro-LED devices and, in particular, micro light-emitting diode displays and pixel structures.

### BACKGROUND

Displays having micro-scale light-emitting diodes (LEDs) are known as micro-LED, mLED, and μLED. As the name implies, micro-LED displays have arrays of micro-LEDs forming the individual pixel elements.

A pixel may be a minute area of illumination on a display screen, one of many from which an image is composed. In other words, pixels may be small discrete elements that together constitute an image as on a display. These primarily square or rectangular-shaped units may be the smallest item of information in an image. Pixels are normally arranged in a two-dimensional (2D) matrix, and are represented using dots, squares, rectangles, or other shapes. Pixels may be the basic building blocks of a display or digital image and with geometric coordinates.

### BRIEF DESCRIPTION OF THE DRAWINGS

FIG. 1 illustrates a schematic of micro LED or OLED display architecture, in accordance with an embodiment of the present disclosure.

FIG. 2 illustrates a cross-sectional view of a pixel structure including a subwavelength antireflection grating, in accordance with an embodiment of the present disclosure.

FIG. 3 is a plot of emission patterns (output brightness) of engineered refraction index layer (e.g., SWAG), compared with a reference micro LED without an engineered refraction index layer, in accordance with an embodiment of the present disclosure.

FIG. 4 includes an image of a moth and a magnified image of a portion of an eye of a moth, in accordance with an embodiment of the present disclosure.

FIG. 5 includes schematics demonstrating the use of a SWAG layer as an index gradient layer to reduce internal reflections and improve extraction efficiency in micro LED displays, in accordance with an embodiment of the present disclosure.

FIG. 6 illustrates a passivation structure having a moth eye pattern fabricated therein, in accordance with an embodiment of the present disclosure.

FIG. 7A is a schematic illustrating an augmented reality display approach, in accordance with an embodiment of the present disclosure.

FIG. 7B is a schematic of augmented reality glasses, in accordance with an embodiment of the present disclosure.

FIGS. 8-10 illustrate cross-sectional views representing various operations in a method of fabricating a micro light emitting diode pixel structure, in accordance with an embodiment of the present disclosure.

FIG. 11A is a block diagram of driver electronics architecture, in accordance with an embodiment of the present disclosure.

FIG. 11B is a block diagram of a pixel circuit including a linearized transconductance amplifier, in accordance with an embodiment of the present disclosure.

FIG. 12 illustrates a circuit for implementing pulse amplitude modulation, in accordance with an embodiment of the present disclosure.

FIG. 13 is a flow diagram illustrating an RGB display production process, in accordance with an embodiment of the present disclosure.

FIG. 14 is a schematic illustration of a display architecture, in accordance with an embodiment of the present disclosure.

FIG. 15 is an electronic device having a display, in accordance with embodiments of the present disclosure.

### DESCRIPTION OF THE EMBODIMENTS

Micro light-emitting diode (LED) displays and pixel structures are described. In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

One or more embodiments described herein are directed to devices and architectures for micro LED displays. To provide context, displays based on inorganic micro LEDs (μLEDs) have attracted increasing attention for applications in emerging portable electronics and wearable computers such as head-mounted displays and wristwatches. Micro LEDs are typically first manufactured on Sapphire or silicon wafers (for example) and then transferred onto a display backplane glass substrate where on which active matrix thin-film transistors have been manufactured.

Micro LED displays promise 3×-5× less power compared to organic LED (OLED) displays. The difference would result in a savings in battery life in mobile devices (e.g., notebook and converged mobility) and can enhance user experience. In an embodiment, micro LED displays described herein consume two-fold less power compared to organic LED (OLED) displays. Such a reduction in power consumption may provide an additional approximately 8 hours of battery life. Such a platform may even outperform platforms based on low power consumption central processing units (CPUs). Embodiments described herein may be associated with one or more advantages such as, but not limited to, high manufacturing yield, high manufacturing throughput (display per hour), and applicability for displays with a diagonal dimension ranging from 2 inches to 15.6 inches.

In a first aspect of the present disclosure, foldable micro LED displays with enhanced light extraction efficiency are described.

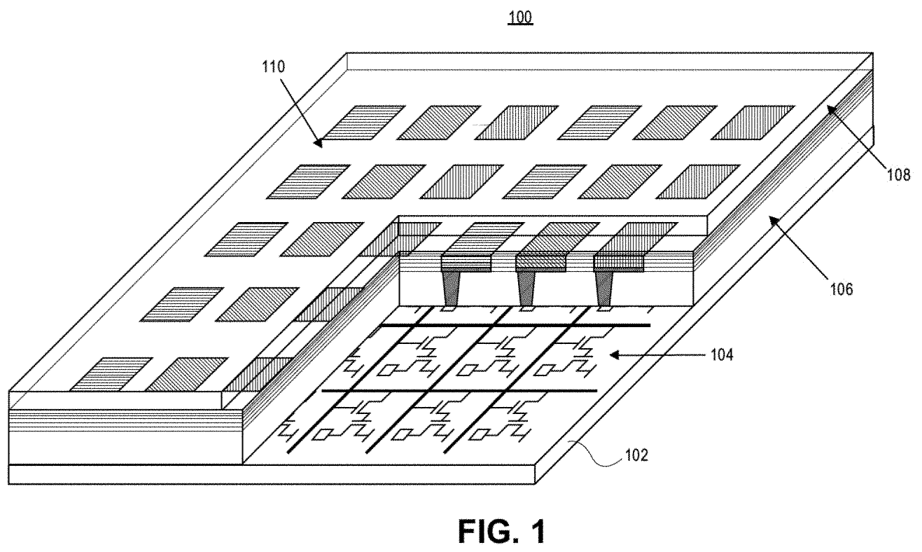

One or more embodiments are directed to approaches and devices for enabling the fabrication of foldable and low power full-color micro light emitting diode (μLED) displays. As an exemplary display architecture, FIG. 1 illustrates a schematic of micro LED or OLED display architecture, in accordance with an embodiment of the present disclosure. Referring to FIG. 1, a micro LED or OLED display 100 includes a backplane 102 having pixel circuits 104 thereon. An insulator 106 is over the pixel circuits 104. Micro LED layers 108 are included over the insulator 106. A transparent electrode 110 is over the micro LED layers 108.

It is to be appreciated that approaches for fabricating a micro LED may include the use of red, green and blue micro LEDs fabricated from gallium nitride (GaN), or the use of blue micro LEDs some of which are in combination with red quantum dots or green quantum dots. However, the former approach may exhibit high power consumption due to inefficient red GaN micro LEDs. The latter approach may exhibit low extraction efficiency due to refractive index mismatch between quantum dot films and air.

In accordance with one or more embodiments of the present disclosure, addressing one or more of the above issues, an engineered refractive index layer is used on top of a quantum dot passivation layer to reduce internal reflection and improve light extraction efficiency. The engineered refractive index layer may be fabricated from subwavelength protrusions on top of the passivation layer used to protect the quantum dots from the environment. The engineered refractive index layer may be referred to as a “subwavelength antireflection grating” or SWAG. In an embodiment, a micro LED pixel structure includes integrated subwavelength structures on the passivation layer of quantum dot films to (1) enhance extraction efficiency and/or (2) tune the viewing angle per each display application.

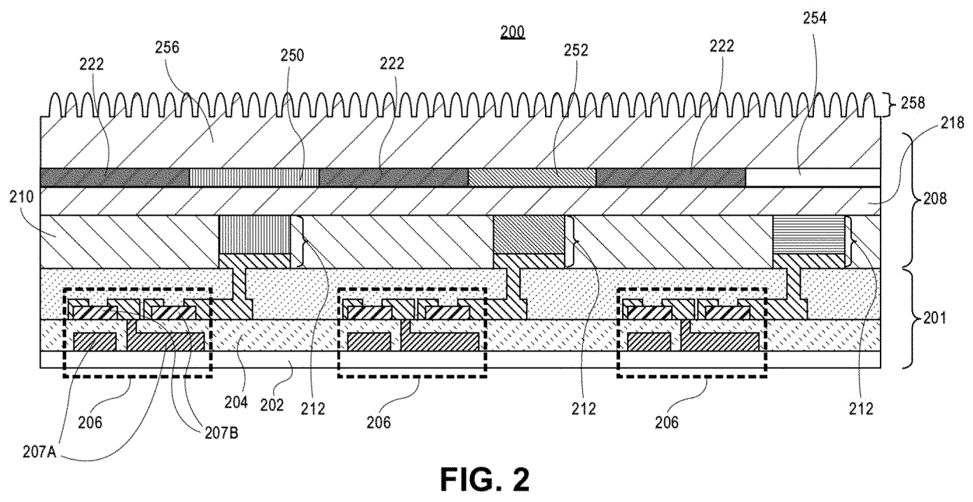

As an exemplary pixel architecture, FIG. 2 illustrates a cross-sectional view of a pixel structure including a subwavelength antireflection grating, in accordance with an embodiment of the present disclosure.

Referring to FIG. 2, a pixel structure 200 includes a backplane 201. The backplane 201 includes a glass substrate 202 having an insulating layer 204 thereon. Pixel thin film transistor (TFT) circuits 206 are included in and on the insulating layer 204. Each of the pixel TFT circuits 206 includes gate electrodes 207A, such as metal gate electrodes, and channels 207B, such as polycrystalline silicon channels or IGZO channels. A portion of the insulating layer 204 may act as a gate dielectric for each of the pixel TFT circuits 206.

Referring again to FIG. 2, the pixel structure 200 includes a front plane 208 on the backplane 201. The front plane 208 includes LEDs in a dielectric layer 210, such as a carbon-doped oxide layer. In an exemplary embodiment, three micro LEDs 212 are included. In a particular embodiment, all micro LEDs 212 are blue micro LEDs. It is to be appreciated that other arrangements may be used, including variation in number and/or colors of micro LEDs included.

Referring again to FIG. 2, the front plane 208 includes a transparent conducting oxide layer 218, such as a layer of indium tin oxide (ITO), as a cathode of the pixel structure 200. A mask layer 222, such as a layer of CrO₂, is on the conducting oxide layer 218. Quantum dot layers or quantum dot-absent layers, such as quantum dot layers 250 and 252 and quantum dot-absent layer 254, are disposed in openings in the mask layer 222 over an associated micro LED. A passivation layer 256 is on or above the mask layer 222 (and on or above the quantum dot layers or quantum dot-absent layers). The passivation layer 256 includes sub-wavelength features 258. The sub-wavelength features 258 may be included for enhancing light extraction.

In an exemplary embodiment, the quantum dot layer 250 is a red quantum dot layer to effectively provide red light from the underlying associated LED 212, the quantum dot layer 252 is a green quantum dot layer to effectively provide green light from the underlying associated LED 212, and layer 254 is a layer absent quantum dots to allow blue light to effectively be emitted from the underlying associated LED 212. It is to be appreciated that other arrangements may be used, including variation in types of quantum dot or quantum dot-absent layers. In still other embodiments, use of appropriate quantum dot or quantum dot absent layers may be used together with green or red LEDs.

In an embodiment, each of the pixel TFT circuits 206 is a circuit such as circuit 1200, described below. Embodiments described herein may be based only on the back plane 201 described above. Embodiments described herein may be based only on the front plane 208 described above.

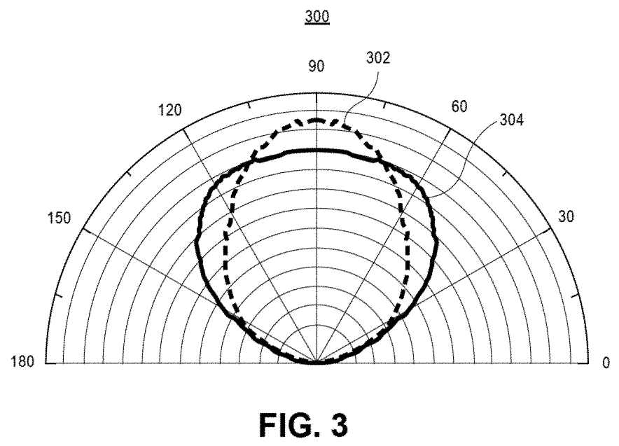

Advantages of implementing one or more embodiments described herein may include one or more of, but need not be limited to, (1) improved light extraction by use of an engineered refractive index layer, (2) a significant reduction in internal reflectivity, or (3) enhanced transmission, which serves to assist with light extraction from the device. As the incident ray effectively “meets no optical discontinuity”, Fresnel reflection can be eliminated. The improvement in light extraction efficiency can be as much as 100% with respect to baseline. As an exemplary radiation pattern, FIG. 3 is a plot 300 of emission patterns (output brightness) of engineered refraction index layer 302 (e.g., SWAG), compared with a reference micro LED 304 without an engineered refraction index layer, in accordance with an embodiment of the present disclosure.

Embodiments described herein may be implemented to enable large scale μLED display manufacturing that brings together three major separate technologies and supply chain bricks: (1) micro LED manufacturing, (2) display manufacturing, and (3) transfer technology tool manufacturing. In a typical display, each pixel is constituted of Red, Green and Blue (RGB) subpixels controlled independently by a matrix of transistors. The idea behind LED displays is to use individual, small LED chips as the sub-pixel. Unlike OLEDs, inorganic LED require high processing temperatures (e.g., greater than 1000° C.) and cannot be “grown” and patterned directly on top of the transistor matrix. In most cases, the micro LED chips are therefore manufactured separately then positioned and connected to the transistor matrix via a pick and place process. Many companies and research organizations are currently working on LED displays. However, volume production at costs compatible with the applications still face multiple engineering and manufacturing challenges. Such challenges include: LED epitaxy quality and homogeneity, efficiency of very small LEDs, sidewall effects, massively parallel chip transfer technologies (e.g. pick and place) with position accuracy and high throughput, cost, handling of small die, etc., interconnects, color conversion, defect management, supply chain, and cost of production.

Micro LED (μLED) display is a type of emissive display technology that uses a matrix of individually-switched self-illuminating inorganic diodes that can be controlled and lit without a master backlight. Inorganic μLEDs have a number of potential advantages over organic LEDs (OLEDs) for display applications including high brightness, longer lifecycle, and imperviousness to image sticking and burn in. Typically, in μLED displays, a desired color and luminance value are created from various combinations of three colors of light emitting elements (red, green and blue).

It is to be appreciated that due to the inorganic nature of the emitting materials of micro LEDs versus OLEDs, the efficiency and narrow emission bands of μLEDs also offer the prospect of significantly improved performance in terms of: energy consumption, color gamut, brightness, contrast (High Dynamic Range), long lifetime and environmental stability (not sensitive to air, moisture), and compatibility with flexible backplane technologies to enable curved or flexible displays. In addition, μLEDs can deliver extremely high pixel density (up to 5000 PPI) which, along with very high brightness, make them ideal for applications such as Augmented Reality (AR) or Head Up Display projectors.

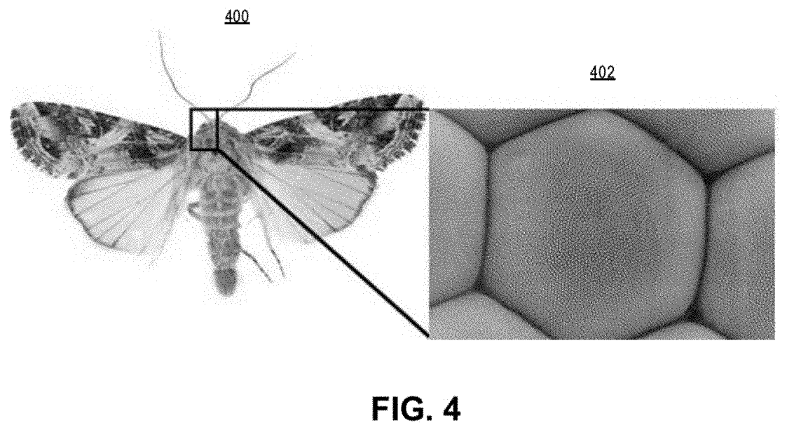

In accordance with one or more embodiments of the present disclosure, subwavelength antireflection (AR) gratings have a moth eye structure for an effective AR coating. For camouflage during the night, moths possess a cornea with extremely low reflection. Electron microscopy reveals that there are pillar-like arrays on the corneal surface of the moth's eye. These arrays have sub-wavelength (SW) height protuberances and are approximately 100 nm in diameter and 200 nm apart from each other. FIG. 4 includes an image 400 of a moth and a magnified image 402 of a portion of an eye of a moth, in accordance with an embodiment of the present disclosure.

In accordance with one or more embodiments, a subwavelength structured (SWS) surface, e.g., a surface-relief grating with a period smaller than the light wavelength, behaves as an antireflection surface. An SWS surface with a deep tapered shape grating may particularly suppress the reflection over a wide spectral bandwidth and a large field of view. Antireflection properties may be improved by decreasing the grating period and increasing the grating depth. The SWS may behave ideally as a gradient index layer with the effective refractive index determined by the filling factor of the grating and the groove mediums.

In an embodiment, a SWAG structure provides broadband antireflection over a wide range of incident light angles when subwavelength textures are taller than t approximately 0.4λ and space closer than l approximately λ/2 nS. For near infra-red (NIR) range with a wavelength equal to or greater than 800 nm, t needs to be equal to or greater than 320 nm, and l approximately 40 nm.

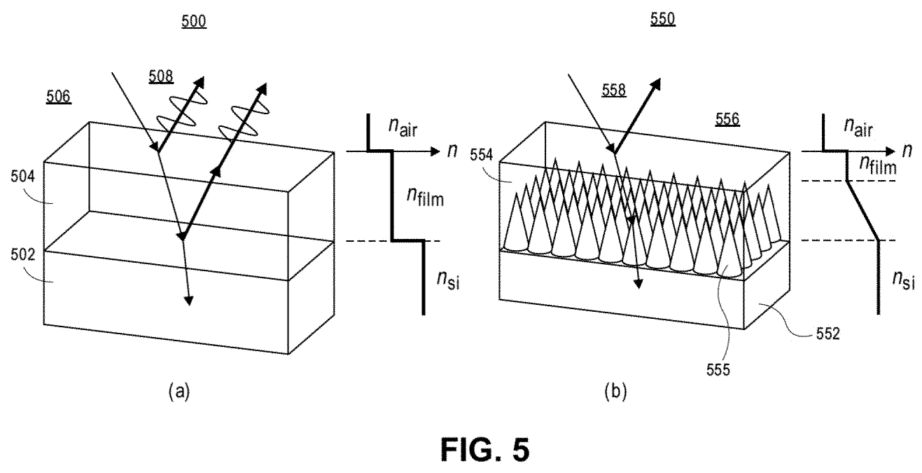

In an example, FIG. 5 includes schematics demonstrating the use of a SWAG layer as an index gradient layer to reduce internal reflections and improve extraction efficiency in micro LED displays, in accordance with an embodiment of the present disclosure. Referring to FIG. 5, in part (a), a conventional structure includes a silicon substrate 502 having a thin film 504 thereon in an air environment 506. Impinging light 508 exhibits thin film interference. In part (b), in an embodiment, a structure includes a silicon substrate 552 having a thin film 554 thereon in an air environment 556. The thin film 554 includes a SWAG layer 555. Impinging light 558 exhibits no interference or essentially no interference.

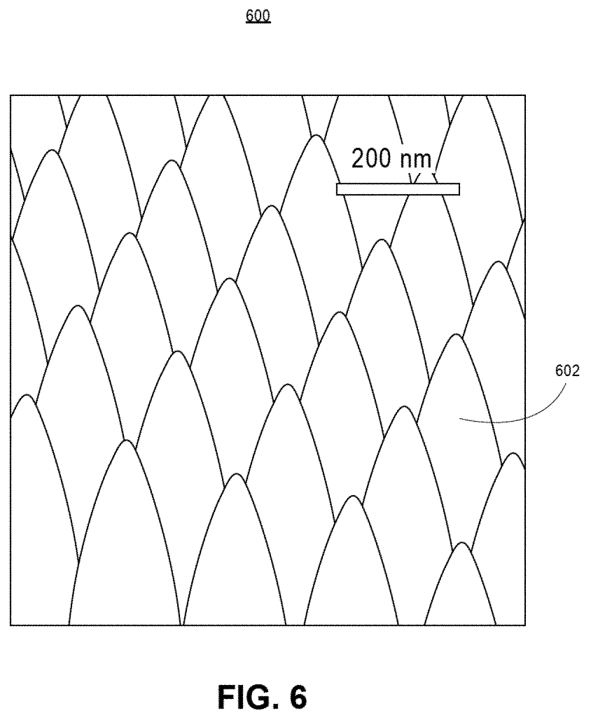

In an embodiment, a SWAG layer is fabricated in or on a passivation layer by directly irradiating silicon using laser pulses. Such structures created using lasers may be referred to as a laser-induced periodic surface structures. FIG. 6 illustrates a passivation structure 600 having a moth eye pattern 602 fabricated therein, in accordance with an embodiment of the present disclosure. The moth eye pattern 602 may improve external quantum efficiency for structures based on a combination of micro LEDs and quantum dot layers.

In accordance with an embodiment of the present disclosure, block copolymer self-assembly and dielectric plasma etching is used to fabricate highly regular dielectric surface nanotextures. The approach may provide precise control over the lateral feature size of the texture (in the range of 10-100 nanometers), vertical profile and feature density. In one embodiment, surface nanotextures are formed on a passivation layer (e.g., dielectric layer) by first self-assembling a cylindrical phase polystyrene-b-polymethylmethacrylate (PS-b-PMMA) block copolymer thin film. The PS-b-PMMA block copolymer thin film may be fabricated by spin-coating and thermal annealing (e.g., 200-300° C.). Appropriate surface pretreatment may facilitate perpendicular orientation of uniformly sized 20-30 nm-diameter PMMA cylindrical micro domains within a PS matrix, locally hexagonally arranged with a separation of 40-60 nm. The periodicity of the nanocylinders may be changed by changing the total molecular weight of the PS-b-PMMA from 50 to 200 kg mol-1, for example. In a particular embodiment, the assembled copolymer films is then exposed to 5-10 sequential cycles of tri(methyl aluminum) and water vapor to selectively load PMMA micro domains with alumina by sequential infiltration synthesis. In one embodiment, the self-assembled alumina pattern provides a rugged template for creating surface nanotextures using dielectric plasma etching. The underlying passivation dielectric may then be anisotropically etched by inductively coupled plasma-reactive ion etching using a gas chemistry of hydrogen bromide, chlorine and oxygen, which may produce a sidewall angle of greater than 70 degrees. The gas mixture and etch parameters may control the nanotexture profile, with t increasing with etch time and taller nanotextures tapering to smaller sizes at their tops.

It is to be appreciated that conventional antireflection coatings typically have transparent quarter wavelength layers of SiOx, TiOx, or SixNy with intermediate or gradient refractive indices. An antireflection coatings (ARC) is formed by single or multiple layer film deposition through various processes such as plasma enhanced chemical vapor deposition and sputtering. These coatings have resonant structures and work effectively only in a limited spectral range and for specific angles of incidence. Also, such coatings may be associated with one or more problems such as thermal mismatch, and lack of adhesiveness.

It is to be appreciated that one dimensional (1-D) surface gratings can be readily produced on surfaces by directly irradiating silicon using laser pulses. Such structures created using lasers may be referred to as laser-induced periodic surface structures. Other methods include the fabrication of “black silicon” based on a subwavelength grating approach. Nanostructures with a periodic nanorod or nanohole array may be fabricated using modified nanosphere lithography to improve the performance of GaN-based structures. In accordance with an embodiment of the present disclosure, a subwavelength structure works in nature as evidenced by the structure and operation of an eye of a moth.

In an embodiment, a micro LED display is fabricated from blue micro LEDs and red, green quantum dots for color conversion. The quantum dots (QDs) are covered with a passivation dielectric layer. Subwavelength antireflection gratings are produced on the surface of the passivation dielectric layer to improve light extraction efficiency, which may lead to lower power consumption. In an embodiment, a pixel structure based on the combination of a SWAG layer with quantum dots (QDs) is used to fabricate low power displays.

In a second aspect of the present disclosure, full color augmented reality display devices and manufacturing methods are described.

To provide context, augmented reality headsets are expected to play an important role in the universe of connected devices. Innovation is needed in augmented reality displays, such as full color (RGB) augmented reality displays. For example, only red (monochromatic) VCSEL-based projection displays are available today. Unfortunately, the use of only one color does not provide the ultimate user experience than would be expected with full color.

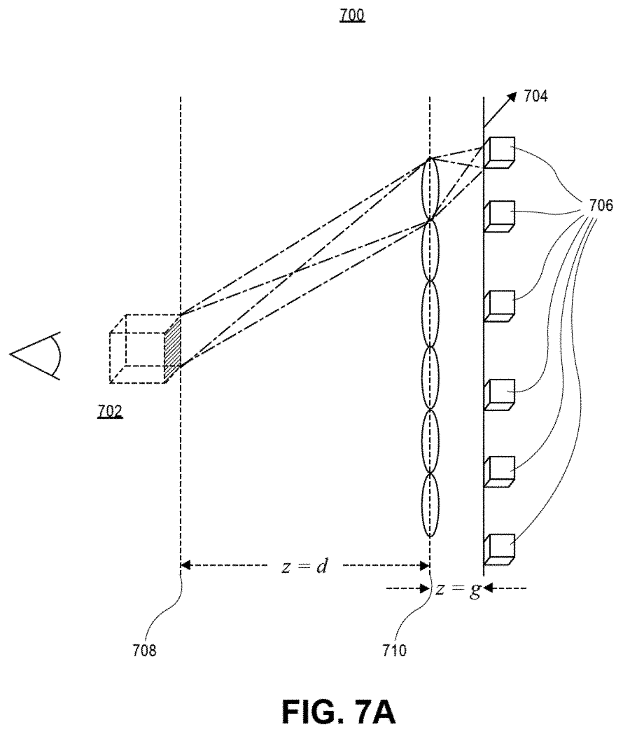

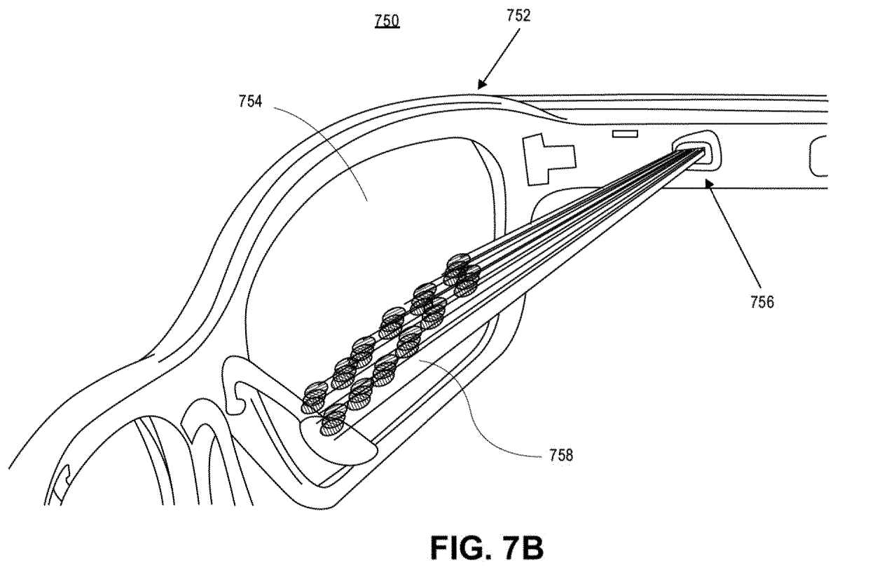

In accordance with one or more embodiments of the present disclosure, a full-color, three-dimensional (3D), and low power augmented reality display device is described. In one embodiment, a micro LED array is used in an integral display architecture for displaying elemental images to save power consumption, improve color gamut, increase contrast ratio, and/or increase brightness. As an example architecture, FIG. 7A is a schematic illustrating an augmented reality display approach 700, in accordance with an embodiment of the present disclosure.

Referring to FIG. 7A, an observer 702 is positioned relative to a micro LED display 704 including individual LED elements 706. The observer 702 is at a reconstruction plane 708. A lenslet array plane 710 is between the reconstruction plane 708 and the micro LED display 704. The value of g is the focal length of each lenslet. The lenslet array size may be 6×6 with total μLED display array size of 0.5 inch diagonal. This results in each elemental image size is 1.5 mm×0.5 mm. When the size of each red, green, and blue subpixel is approximately 4 microns, the pixel resolution is approximately 2560 ppi. Thus, in an embodiment, implementing manufacturing methods described herein yield unique display structures with high resolution (e.g., greater than 2500 PPI).

FIG. 7B is a schematic 750 of augmented reality glasses 752, in accordance with an embodiment of the present disclosure. Referring to FIG. 7B, the augmented reality glasses 752 include a lens 754 in a frame including an arm. A micro LED structure 756 is included in the arm of the frame 752. A display 758 is projected on the lens 754.

Advantages of implementing one or more embodiments disclosed herein may include, but need not be limited to, (1) full color display, (2) high brightness (e.g., excellent outdoors performance), (3) low power consumption (e.g., using solid-state LEDs with high power efficiency), and/or (4) low manufacturing cost.

It is to be appreciated that a holographic three-dimensional (3D) display has been also considered as an alternative way to the current stereoscopic display having serious drawbacks of eye fatigue and visual discomfort. The holographic method, however, suffers from several practical problems, which include the high complexity for full-color display since it must employ a time or spatial-multiplexing scheme for simultaneous displaying of three-color hologram patterns. In conventional holographic optical image reconstructions, speckle noise may also be present due to coherent illumination (e.g., with a laser). By contrast, in accordance with an embodiment of the present disclosure, using μLEDs to replace a laser as a light source, a speckle noise problem may be eliminated since μLEDs are incoherent light sources. However, in one embodiment, the reconstruction quality is lower in the μLEDs case due to spectral properties of the light source.

It is to be appreciated that conventional integral imaging systems are composed of two stages: generation of elemental two dimensional (2D) images of a 3D object/scene via a computer, and a display stage which integrates the elemental images for reconstruction. The elemental images are displayed on an LCD display array and the reconstruction is observed through a lenslet array. The graphical processing unit (GPU) may be used to further increase the computation speed. In an embodiment, a holographic data is reconstructed by an integral imaging display.

In one aspect, a display assembly method involves fabricating micro LED displays on silicon wafers. In an embodiment, a manufacturing approach involves first providing two types of wafers. A first wafer includes μLED arrays with a very small pitch (e.g., less than 5 μm) fabricated on, e.g., 300 mm silicon wafers. In an example, red, green and blue LEDs are manufactured monolithically. In one embodiment, the LED active layers are composed of Indium Gallium Nitride (InGaN) with different Indium composition corresponding to different colors (e.g., blue color LEDs have approximately 20% indium, green color LEDs have approximately 300/% indium, and red color LEDs have approximately 40% indium).

A second wafer, such as a 300 mm wafer, is prepared with driver circuit arrays (e.g., corresponding to the μLED arrays mentioned above). The driver circuit arrays may be fabricated to include CMOS devices on silicon wafers (e.g., 22 nm node, 32 nm node, 45 nm node, 65 nm node, 90 nm node, 130 nm node, or 180 nm node). Wafer-to-wafer bonding is then performed to couple the above two wafers using wafer bonding technology with an alignment accuracy of, e.g., ±0.5 μm or better.

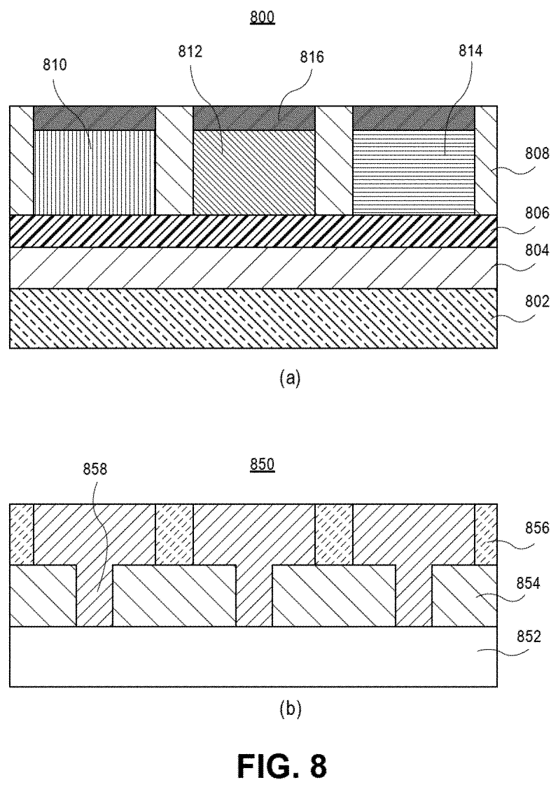

As an example, FIGS. 8-10 illustrate cross-sectional views representing various operations in a method of fabricating a micro light emitting diode pixel structure, such as a display for use in an augmented reality micro LED display, in accordance with an embodiment of the present disclosure.

Referring to part (a) of FIG. 8, structure 800 includes a second wafer 802, such as silicon wafer having an aluminum nitride (AlN) 804 and nucleation layer 806 thereon. Wafer 802 includes a plurality of micro light emitting diode devices 810/812/814 in a second dielectric 808 thereon. In one embodiment, the plurality of micro light emitting diode devices includes a red micro light emitting diode device 810, a green micro light emitting diode device 812, and a blue micro light emitting diode device 814. A metal layer 816, such as a copper layer, may be included as an anode layer, as is depicted.

Referring to part (b) of FIG. 8, structure 850 includes a first wafer 852 having a plurality of conductive interconnect structures 858 in a first dielectric layer 854/856 thereon. In one embodiment, first dielectric layer 854/856 includes a first low-k portion 854 and a second low-k portion 856, as is depicted. In one embodiment, the first wafer 852 is a silicon substrate including metal oxide semiconductor (CMOS) devices or thin film transistor (TFT) devices coupled to the plurality of conductive interconnect structures 858.

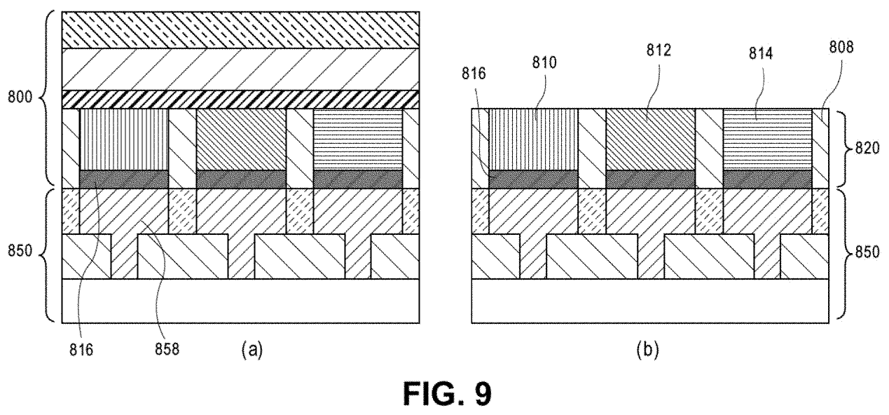

Referring to part (a) of FIG. 9, structures 800 and 850, i.e., first and second wafers, are coupled to provide individual ones of the plurality of micro light emitting diode devices 810/812/814 electrically coupled to a corresponding one of the plurality of conductive interconnect structures 858, e.g., by wafer-to-wafer bonding. The bonding may be through metal layer 816, as is depicted.

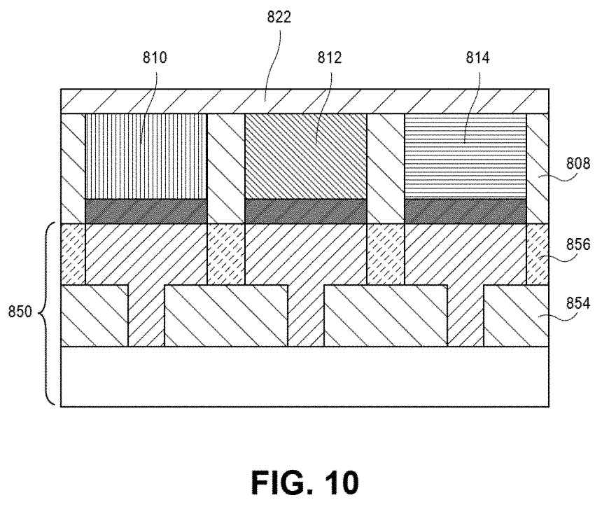

Referring to part (b) of FIG. 9, the second wafer 802 (and, if included, layers 804 and 806) are removed to expose the plurality of micro light emitting diode devices 810/812/814. Referring to FIG. 10, a transparent conducting oxide layer 822 is formed on the plurality of micro light emitting diode devices 810/812/814 and on the second dielectric layer 808.

Referring again to FIGS. 8-10, a micro light emitting diode pixel structure includes a substrate 852 having a plurality of conductive interconnect structures 858 in a first dielectric layer 854/856 thereon. A plurality of micro light emitting diode devices 810/812/814 is in a second dielectric layer 808 above the first dielectric layer 854/856. Individual ones of the plurality of micro light emitting diode devices 810/812/814 is electrically coupled to a corresponding one of the plurality of conductive interconnect structures 858. The second dielectric layer 808 is separate and distinct from the first dielectric layer 854/856. A transparent conducting oxide layer 822 is disposed on the plurality of micro light emitting diode devices 810/812/814 and on the second dielectric layer 808.

In one embodiment, substrate 852 is a silicon substrate including metal oxide semiconductor (CMOS) devices or thin film transistor (TFT) devices coupled to the plurality of conductive interconnect structures 858. In one embodiment, the plurality of micro light emitting diode devices 810/812/814 includes a single red micro light emitting diode device 810, a single green micro light emitting diode device 812, and a single blue micro light emitting diode device 814. In one embodiment, the first 854/856 and second 808 dielectric layers are low-k dielectric layers. In one embodiment, the transparent conducting oxide layer 822 is an indium tin oxide (ITO) layer.

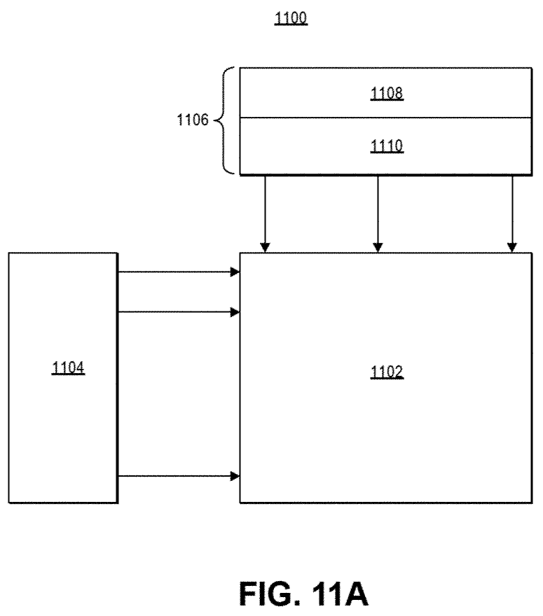

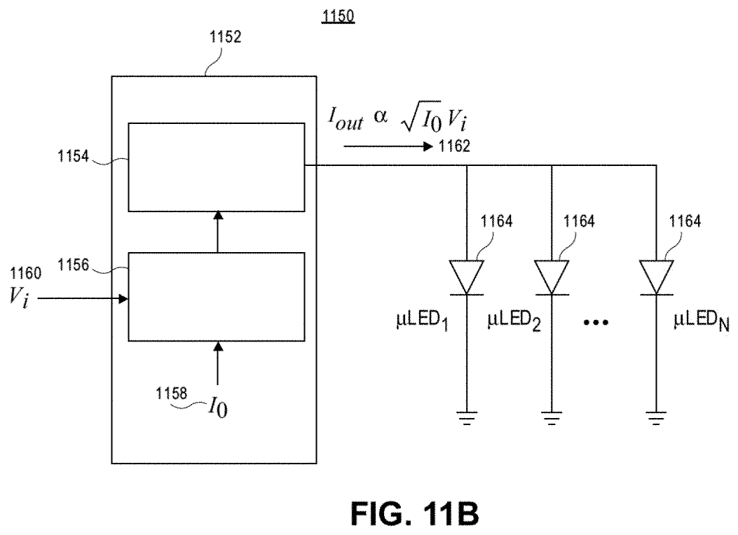

In accordance with one or more embodiments of the present disclosure, a pulse amplitude modulation driving scheme and circuit are described. For example, FIG. 11A is a block diagram 1100 of driver electronics architecture, in accordance with an embodiment of the present disclosure. Referring to the display system schematic of FIG. 11A, a μLED array 1102 (such as an OLED or LED) is driven by a row driver 1104 and a column driver 1106. Each column driver 1106 will has 8 bit SRAM 1108 and a 256 bit DAC or 10 bit PAM 1110. The output of the DAC 1110 is a pulse having an amplitude determined by the current density required to achieve peak power efficacy. The width of the pulse is a function of the integrated current density needed by the micro LED to achieve a desired gray level and brightness.

FIG. 11B is a block diagram of a pixel circuit including a linearized transconductance amplifier, in accordance with an embodiment of the present disclosure. Referring to FIG. 11B, a circuit 1150 includes a pixel circuit 1152. Pixel circuit 1152 includes a current mirror 1154 and a linearlized transconductance amplifier 1156. A pulsed current source 1158 is provided. Input data 1160 is input to pixel circuit 1152. Output data 1162 is output from pixel circuit 1152 and used to drive one or more micro LED devices 1164.

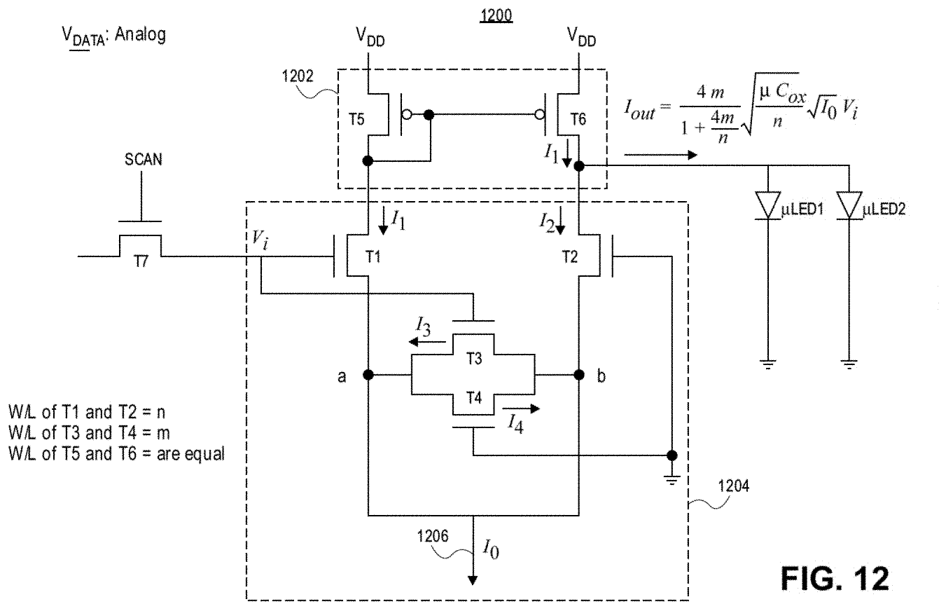

A capacitor-less pixel driver circuit may be used for high PPI displays, such as for AR devices. In an example, FIG. 12 illustrates a circuit 1200 for implementing pulse amplitude modulation, in accordance with an embodiment of the present disclosure. The circuit 1200 includes a current mirror 1202 and a linearized transconductance amplifier 1204. In one embodiment, the current mirror 1202 is based on two P-type transistors, as is depicted. In the pulse amplitude modulation circuit 1200, an input voltage signal is driven by a digital to analog convertor (DAC). The linearized transconductance amplifier 1204 converts the voltage to current. At the bottom of circuit 1200, the current itself gets switched to generate a pulse amplitude modulated current (e.g., bias current 1206) as a pulsed current source. The width of the pulse is fixed by the amount of current density needed for representing a Gray level 1.

Regarding circuit analysis, referring again to the pulse amplitude modulation circuit 1200 of FIG. 12, the following equations hold.

$$\begin{matrix}{V}_{a} = {V}_{i} - {V}_{GS 1} = {V}_{i} - {V}_{TH} - \sqrt{\frac{2 {I}_{1}}{μ {C}_{ox} n}} & ( 1 ) \\ {V}_{b} = - {V}_{GS 2} = - {V}_{TH} - \sqrt{\frac{2 {I}_{1}}{μ {C}_{ox} n}} & ( 2 ) \\ {I}_{1} - {I}_{2} = 2 ( {I}_{3} - {I}_{4} ) & ( 3 ) \\ {I}_{3} = m μ {C}_{ox} [ ( {V}_{i} - {V}_{b} - {V}_{TH} ) {V}_{ab} - \frac{1}{2} {V}_{ab}^{2} ] & ( 4 ) \\ {I}_{4} = m μ {C}_{ox} [ ( 0 - {V}_{a} - {V}_{TH} ) {V}_{ba} - \frac{1}{2} {V}_{ba}^{2} ] & ( 5 ) \\ {I}_{1} = \frac{1}{2} {I}_{0} + {I}_{3} - {I}_{4} = \frac{1}{2} {I}_{0} + x & ( 6 ) \\ {I}_{2} = \frac{1}{2} {I}_{0} - {I}_{3} + {I}_{4} = \frac{1}{2} {I}_{0} - x & ( 7 )\end{matrix}$$

Using equations (1)-(5), the following equation can be derived without any approximations.

$${I}_{3} - {I}_{4} = \frac{n m}{n + 4 m} \sqrt{\frac{2 μ {C}_{ox}}{n}} ( \sqrt{{I}_{1}} + \sqrt{{I}_{2}} ) {V}_{i} \qquad ( 8 )$$

Using equations (6) and (7) into (8), the following is obtained.

$$x = \frac{n m}{n + 4 m} \sqrt{\frac{2 μ {C}_{ox}}{n}} ( \sqrt{\frac{{I}_{0}}{2} + x} + \sqrt{\frac{{I}_{0}}{2} - x} ) {V}_{i} \qquad ( 9 )$$

Solving the quadratic equation in x, the following equation is derived.

$${I}_{out} = {I}_{1} - {I}_{2} = \frac{4 m}{1 + 4 m / n} \sqrt{\frac{μ {C}_{ox}}{n}} \sqrt{{I}_{0}} {V}_{i} \qquad ( 10 )$$

Equation (10) is valid when the following condition is satisfied.

$${V}_{i} ≪ \frac{n + 4 m}{n m} \sqrt{\frac{n}{4}} \sqrt{\frac{{I}_{0}}{μ {C}_{ox}}} \qquad ( 11 )$$

Combining equations (10) and (11) the following condition is determined.

I₀>>Iₒᵤₜ/2=5Iₒᵤₜ (12)

In an embodiment, for a driving method, each of the gray levels is represented by a specific voltage (Vᵢ) in equation (10). If V1 corresponds to the lowest gray level, and V10 corresponds to 1024^{th} gray level (e.g., in a 10-bit architecture), the DAC should provide voltage levels with resolution equal to (V10−V1)/1024 volts.

The highest gray level current is given by the following.

$${I}_{GL , max} = {I}_{out} \frac{{t}_{p}}{1 / ( {N}_{r} f )} = \frac{{I}_{0}}{5} {t}_{p} {N}_{r} f \qquad ( 13 )$$

Thus, the current I₀ should be a pulse with fixed width (tₚ) and amplitude that is equal to 5 I_{GL,max}/(tₚ·f·Nᵣ). Here, I_{GL,max} is the micro LED current that corresponds to a highest gray level, f is the frame rate (e.g. 120 Hz), and Nᵣ is the number of rows in the active-matrix. The pulse amplitude should also equal to the current at which the micro LED power efficacy peaks (JₚL²) where Jₚ is the current density at peak power efficacy, and L is the size of the micro LED.

Therefore, the following holds.

JₚL²=5I_{GL,max}/(tₚ·f·Nᵣ) (14)

The pulse width can thus be determined to be the following.

tₚ=5I_{GL,max}/(f·Nᵣ·Jₚ·L²) (15)

In equation (15), I_{GL,max} is the current corresponding to the highest gray level brightness. If it is assumed that I_{GL,max}=10 nA, f=120 Hz, Nᵣ=1440, Jₚ=1 A/cm², and L=5 μm, then tₚ≈1.15 μs.

In an embodiment, for pulse amplitude modulation, circuit 400 shown in FIG. 12 performs pulse amplitude modulation according to the following.

$${I}_{out} = \frac{4 m}{1 + 4 m / n} \sqrt{\frac{μ {C}_{ox}}{n}} \sqrt{{I}_{0}} {V}_{i} \qquad ( 16 )$$

In equation (16), the pulse current (I₀) is modulated by the input DATA voltage Vᵢ. The pulse height and pulse width tₚ are designed as described above.

To provide further context, LED arrays produce their own light in response to current flowing through the individual elements of the array. A variety of different LED-like luminescent sources have been used for such displays. One or more embodiments described herein utilize electroluminescent materials in μLEDs made of, for example, GaN, InGaN, or AlInGaP materials. Electrically, such devices behave like diodes with forward “on” voltage drops ranging from 1.9 volts (V) to 5 V, depending on the color and electrode quality.

Unlike liquid crystal displays (LCDs), μLEDs are current driven devices. However, they may be similarly arranged in a two-dimensional array (matrix) of elements to form a display. Active-matrix μLED displays typically use current control circuits integrated with the display itself, with one control circuit corresponding to each individual element on the substrate, to create high-resolution color graphics with a high refresh rate. Such a structure results in a matrix of devices, where one (or more) device is formed at each point where a row overlies a column. There will generally be at least M×N devices in a matrix having M rows and N columns. Typical devices function like light emitting diodes (LEDs), which conduct current and luminesce when voltage of one polarity is imposed across them, and block current when voltage of the opposite polarity is applied. To control such individual μLED devices located at the matrix junctions, it may be useful to have two distinct driver circuits, one to drive the columns and one to drive the rows. It is conventional to sequentially scan the rows (e.g., conventionally connected to device cathodes) with a driver switch to a known voltage such as ground, and to provide another driver to drive the columns (which are conventionally connected to device anodes). In operation, information is transferred to the matrix display by scanning each row in sequence. During each row scan period, each column connected to an element intended to emit light is also driven.

In contrast to conventional integral display architecture based on liquid crystal displays (LCDs), one or more embodiments described herein include the use of a micro LED emissive display which results in overall lower power. Monolithic RGB micro LED wafers may provide full color augmented reality display arrays. Wafer-to-wafer bonding approaches described herein provide a unique device structure that can be easily detected (e.g., metal-to-metal bonding structure and the monolithic RGB pixels). A driver circuit described herein may consume relatively very little area to fit into small pixels of high resolution (high PPI) AR displays.

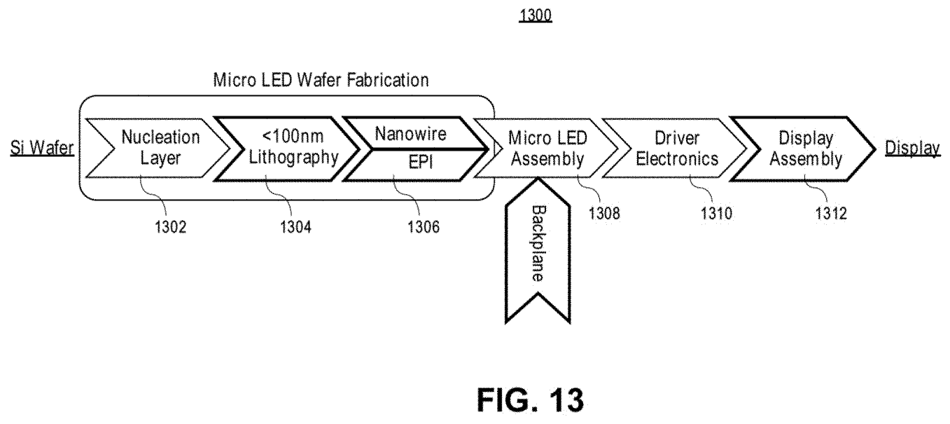

In another aspect, FIG. 13 is a flow diagram 1300 illustrating an RGB display production process, in accordance with an embodiment of the present disclosure. Referring to flow diagram 1300, at operation 1302, a silicon (Si) wafer has a nucleation layer formed thereon, such as a patterned conductive/dielectric nucleation layer. At operation 1304, sub 100 nm lithography is used to pattern a layer on the nucleation layer, or to pattern the nucleation layer. At operation 1306, nanowire growth is performed on the nucleation layer, e.g., by epitaxial deposition. At operation 1308, a backplane is introduced into the micro LED assembly process. At operation 1310, driver electrons are fabricated. At operation 1312, display assembly is performed to finally provide a display.

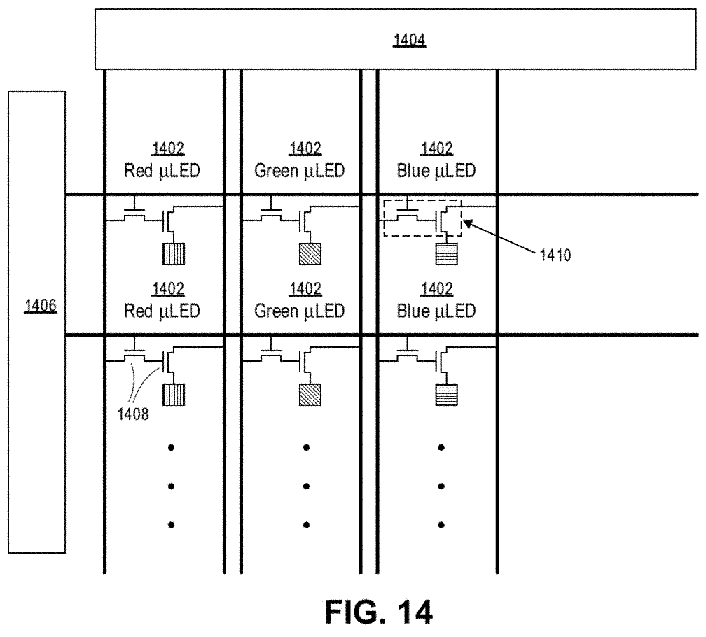

FIG. 14 is a schematic illustration of a display architecture, in accordance with an embodiment of the present disclosure. Referring to FIG. 14, micro LEDs 1402 are arranged in a matrix. The micro LEDs are driven through “Data Driver” 1404 and “Scan Driver” 1406 chips. Thin film transistors 1408 are used to make “pixel driver circuits” 1410 for each micro LED. In an embodiment, the micro LEDs are fabricated on a silicon wafer then transferred to a glass substrate called “backplane” where the “pixel driver circuits” 1410 have been fabricated using thin film transistors. Although represented simplistically in FIG. 14, it is to be appreciated that the pixel driver circuits 1410 may be or include a driver circuit such as circuit 1200, described herein.

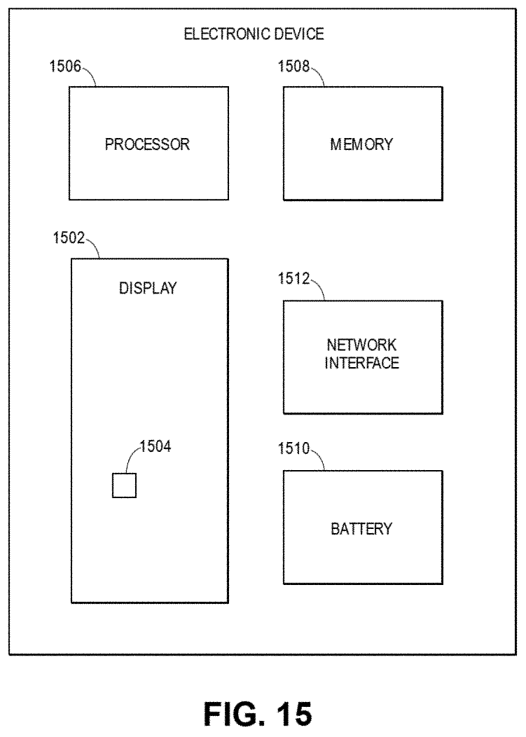

FIG. 15 is an electronic device having a display, in accordance with embodiments of the present disclosure. Referring to FIG. 15, an electronic device 1500 has a display or display panel 1502 with a micro-structure 1504. The display may also have glass layers and other layers, circuitry, and so forth. The display panel 1502 may be a micro-LED display panel. As should be apparent, only one microstructure 1504 is depicted for clarity, though a display panel 1502 will have an array or arrays of microstructures including nanowire LEDs.

The electronic device 1500 may be a mobile device such as smartphone, tablet, notebook, smartwatch, and so forth. The electronic device 1500 may be a computing device, stand-alone display, television, display monitor, vehicle computer display, the like. Indeed, the electronic device 1500 may generally be any electronic device having a display or display panel.

The electronic device 1500 may include a processor 1506 (e.g., a central processing unit or CPU) and memory 1508. The memory 1508 may include volatile memory and nonvolatile memory. The processor 1506 or other controller, along with executable code store in the memory 1508, may provide for touchscreen control of the display and well as for other features and actions of the electronic device 1500.

In addition, the electronic device 1500 may include a battery 1510 that powers the electronic device including the display panel 1502. The device 1500 may also include a network interface 1512 to provide for wired or wireless coupling of the electronic to a network or the internet. Wireless protocols may include Wi-Fi (e.g., via an access point or AP), Wireless Direct®, Bluetooth®, and the like. Lastly, as is apparent, the electronic device 1500 may include additional components including circuitry and other components.

Thus, embodiments described herein include micro light-emitting diode displays and pixel structures.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### Example Embodiment 1

A micro light emitting diode pixel structure includes a plurality of micro light emitting diode devices in a dielectric layer. A transparent conducting oxide layer is disposed above the dielectric layer. A passivation layer is above the transparent conducting oxide layer, the passivation layer having an outer surface including sub-wavelength features.

### Example Embodiment 2

The micro light emitting diode pixel structure of example embodiment 1, further including a mask layer between the transparent conducting oxide layer and the passivation layer, and one or more quantum dot layers disposed in corresponding one or more openings in the mask layer, individual ones of the one or more quantum dot layers over a corresponding one of the plurality of micro light emitting diode devices.

### Example Embodiment 3

The micro light emitting diode pixel structure of example embodiment 2, further including one or more quantum dot-absent layers disposed in corresponding one or more openings in the mask layer, individual ones of the one or more quantum dot-absent layers over a corresponding one of the plurality of micro light emitting diode devices.

### Example Embodiment 4

The micro light emitting diode pixel structure of example embodiment 2 or 3, wherein the plurality of micro light emitting diode devices is a plurality of plurality of blue micro light emitting diode devices, and wherein the one or more quantum dot layers include at least one green quantum dot layer and at least one red quantum dot layer.

### Example Embodiment 5

The micro light emitting diode pixel structure of example embodiment 1, 2, 3 or 4, wherein the passivation layer includes a material selected from the group consisting of SiOx, TiOx, and SixNy.

### Example Embodiment 6

The micro light emitting diode pixel structure of example embodiment 1, 2, 3, 4 or 5, wherein the sub-wavelength features of the passivation layer include height protuberances approximately 100 nanometers in diameter with a spacing of approximately 200 nanometers.

### Example Embodiment 7

The micro light emitting diode pixel structure of example embodiment 1, 2, 3, 4, 5 or 6, wherein the sub-wavelength features include a moth eye pattern.

### Example Embodiment 8

The micro light emitting diode pixel structure of example embodiment 1, 2, 3, 4, 5, 6 or 7, wherein the plurality of micro light emitting diode devices is a plurality of GaN nanowire-based micro light emitting diode devices.

### Example Embodiment 9

The micro light emitting diode pixel structure of example embodiment 1, 2, 3, 4, 5, 6, 7 or 8, wherein the plurality of micro light emitting diode devices, the transparent conducting oxide layer, and the passivation layer form a front plane of the micro light emitting diode pixel structure, and wherein the micro light emitting diode pixel structure further includes a backplane disposed beneath the front plane, the backplane including a glass substrate having an insulating layer disposed thereon; and a plurality of pixel thin film transistor circuits disposed in and on the insulating layer, each of the pixel thin film transistor circuits including a gate electrode and a channel including polycrystalline silicon or indium gallium zinc oxide (IGZO).

### Example Embodiment 10

The micro light emitting diode pixel structure of example embodiment 9, wherein each of the pixel thin film transistor circuits is to drive at least one of the plurality of micro light emitting diode devices.

### Example Embodiment 11

The micro light emitting diode pixel structure of example embodiment 9 or 10, wherein each of the pixel thin film transistor circuits includes a current mirror and a linearized transconductance amplifier coupled to the current mirror.

### Example Embodiment 12

The micro light emitting diode pixel structure of example embodiment 11, wherein the current mirror of each of the pixel thin film transistor circuits includes two P-type transistors.

### Example Embodiment 13

A micro light emitting diode pixel structure includes a substrate having a plurality of conductive interconnect structures in a first dielectric layer thereon. A plurality of micro light emitting diode devices is in a second dielectric layer above the first dielectric layer, individual ones of the plurality of micro light emitting diode devices electrically coupled to a corresponding one of the plurality of conductive interconnect structures, wherein the second dielectric layer is separate and distinct from the first dielectric layer. A transparent conducting oxide layer is disposed on the plurality of micro light emitting diode devices and on the second dielectric layer.

### Example Embodiment 14

The micro light emitting diode pixel structure of example embodiment 13, wherein the substrate is a silicon substrate including metal oxide semiconductor (CMOS) devices or thin film transistor (TFT) devices coupled to the plurality of conductive interconnect structures.

### Example Embodiment 15

The micro light emitting diode pixel structure of example embodiment 13 or 14, wherein the plurality of micro light emitting diode devices includes a single red micro light emitting diode device, a single green micro light emitting diode device, and a single blue micro light emitting diode device.

### Example Embodiment 16

The micro light emitting diode pixel structure of example embodiment 13, 14 or 15, wherein the first and second dielectric layers are low-k dielectric layers.

### Example Embodiment 17

The micro light emitting diode pixel structure of example embodiment 13, 14, 15 or 16, wherein the transparent conducting oxide layer is an indium tin oxide (ITO) layer.

### Example Embodiment 18

A method of fabricating a micro light emitting diode pixel structure includes providing a first wafer having a plurality of conductive interconnect structures in a first dielectric layer thereon. The method also includes providing a second wafer having a plurality of micro light emitting diode devices in a second dielectric thereon. The method also includes coupling the first and second wafers to provide individual ones of the plurality of micro light emitting diode devices electrically coupled to a corresponding one of the plurality of conductive interconnect structures. The method also includes removing the second wafer. The method also includes forming a transparent conducting oxide layer on the plurality of micro light emitting diode devices and on the second dielectric layer.

### Example Embodiment 19

The micro light emitting diode pixel structure of example embodiment 18, wherein the first wafer is a silicon substrate including metal oxide semiconductor (CMOS) devices or thin film transistor (TFT) devices coupled to the plurality of conductive interconnect structures.

### Example Embodiment 20

The micro light emitting diode pixel structure of example embodiment 18 or 19, wherein the plurality of micro light emitting diode devices includes a red micro light emitting diode device, a green micro light emitting diode device, and a blue micro light emitting diode device.

### Example Embodiment 21

The micro light emitting diode pixel structure of example embodiment 18, 19 or 20, wherein the first and second dielectric layers are low-k dielectric layers.

### Example Embodiment 22

The micro light emitting diode pixel structure of example embodiment 18, 19, 20 or 21, wherein the transparent conducting oxide layer is an indium tin oxide (ITO) layer.

What is claimed is:

1. A micro light emitting diode pixel structure, comprising:
a plurality of micro light emitting diode devices in a dielectric layer;
a transparent conducting oxide layer disposed above the dielectric layer; and
a passivation layer above the transparent conducting oxide layer, the passivation layer having an outer surface comprising sub-wavelength features.

2. The micro light emitting diode pixel structure of claim 1, further comprising:
a mask layer between the transparent conducting oxide layer and the passivation layer; and
one or more quantum dot layers disposed in corresponding one or more openings in the mask layer, individual ones of the one or more quantum dot layers over a corresponding one of the plurality of micro light emitting diode devices.

3. The micro light emitting diode pixel structure of claim 2, further comprising:
one or more quantum dot-absent layers disposed in corresponding one or more openings in the mask layer, individual ones of the one or more quantum dot-absent layers over a corresponding one of the plurality of micro light emitting diode devices.

4. The micro light emitting diode pixel structure of claim 3, wherein the plurality of micro light emitting diode devices is a plurality of plurality of blue micro light emitting diode devices, and wherein the one or more quantum dot layers comprise at least one green quantum dot layer and at least one red quantum dot layer.

5. The micro light emitting diode pixel structure of claim 1, wherein the passivation layer comprises a material selected from the group consisting of SiOx, TiOx, and SixNy.

6. The micro light emitting diode pixel structure of claim 1, wherein the sub-wavelength features of the passivation layer comprise height protuberances approximately 100 nanometers in diameter with a spacing of approximately 200 nanometers.

7. The micro light emitting diode pixel structure of claim 1, wherein the sub-wavelength features comprise a moth eye pattern.

8. The micro light emitting diode pixel structure of claim 1, wherein the plurality of micro light emitting diode devices is a plurality of GaN nanowire-based micro light emitting diode devices.

9. The micro light emitting diode pixel structure of claim 1, wherein the plurality of micro light emitting diode devices, the transparent conducting oxide layer, and the passivation layer form a front plane of the micro light emitting diode pixel structure, and wherein the micro light emitting diode pixel structure further comprises a backplane disposed beneath the front plane, the backplane comprising:
a glass substrate having an insulating layer disposed thereon; and
a plurality of pixel thin film transistor circuits disposed in and on the insulating layer, each of the pixel thin film transistor circuits comprising a gate electrode and a channel comprising polycrystalline silicon or indium gallium zinc oxide (IGZO).

10. The micro light emitting diode pixel structure of claim 9, wherein each of the pixel thin film transistor circuits is to drive at least one of the plurality of micro light emitting diode devices.

11. The micro light emitting diode pixel structure of claim 9, wherein each of the pixel thin film transistor circuits comprises a current mirror and a linearized transconductance amplifier coupled to the current mirror.

12. The micro light emitting diode pixel structure of claim 11, wherein the current mirror of each of the pixel thin film transistor circuits comprises two P-type transistors.

13. A micro light emitting diode pixel structure, comprising:
a substrate having a plurality of conductive interconnect structures in a first dielectric layer thereon,
a plurality of micro light emitting diode devices in a second dielectric layer above the first dielectric layer, individual ones of the plurality of micro light emitting diode devices electrically coupled to a corresponding one of the plurality of conductive interconnect structures, wherein the second dielectric layer is separate and distinct from the first dielectric layer; and
a transparent conducting oxide layer disposed on the plurality of micro light emitting diode devices and on the second dielectric layer.

14. The micro light emitting diode pixel structure of claim 13, wherein the substrate is a silicon substrate comprising metal oxide semiconductor (CMOS) devices or thin film transistor (TFT) devices coupled to the plurality of conductive interconnect structures.

15. The micro light emitting diode pixel structure of claim 13, wherein the plurality of micro light emitting diode devices comprises a single red micro light emitting diode device, a single green micro light emitting diode device, and a single blue micro light emitting diode device.

16. The micro light emitting diode pixel structure of claim 13, wherein the first and second dielectric layers are low-k dielectric layers.

17. The micro light emitting diode pixel structure of claim 13, wherein the transparent conducting oxide layer is an indium tin oxide (ITO) layer.

18. A method of fabricating a micro light emitting diode pixel structure, the method comprising:
providing a first wafer having a plurality of conductive interconnect structures in a first dielectric layer thereon;
providing a second wafer having a plurality of micro light emitting diode devices in a second dielectric thereon;
coupling the first and second wafers to provide individual ones of the plurality of micro light emitting diode devices electrically coupled to a corresponding one of the plurality of conductive interconnect structures;
removing the second wafer; and
forming a transparent conducting oxide layer on the plurality of micro light emitting diode devices and on the second dielectric layer.

19. The method of claim 18, wherein the first wafer is a silicon substrate comprising metal oxide semiconductor (CMOS) devices or thin film transistor (TFT) devices coupled to the plurality of conductive interconnect structures.

20. The method of claim 18, wherein the plurality of micro light emitting diode devices comprises a red micro light emitting diode device, a green micro light emitting diode device, and a blue micro light emitting diode device.

21. The method of claim 18, wherein the first and second dielectric layers are low-k dielectric layers.

22. The method of claim 18, wherein the transparent conducting oxide layer is an indium tin oxide (ITO) layer.
